(19) United States
(12) Patent Application Publication
(10) Pub. No.: US 2002/0126455 A1
(43) Pub. Date: Sep. 12, 2002

(54) Tiled microelectromechanical device modules and fabrication methods

(76) Inventor: Robert L. Wood, Cary, NC (US)

Correspondence Address: MYERS BIGEL SIBLEY & SAJOVEC, PO BOX 37428, RALEIGH, NC, 27627, US

(21) Appl. No.: 10/071,106

(22) Filed: Feb. 8, 2002

Related U.S. Application Data
(60) Provisional application No. 60/268,784, filed on Feb. 14, 2001.

(51) Int. Cl. H05K 7/00

(52) U.S. Cl. 361/728

(57) ABSTRACT

Multiple microelectromechanical (MEM) device substrates, such as MEM mirror substrates, are tiled on a base substrate. Each MEM device substrate can include one or more MEM devices such as mirrors. By including one or a relatively small number of devices on a MEM device substrate, the MEM device substrate can be manufactured with relatively high yield and can be tested prior to tiling onto the base substrate. The separate MEM device substrates and base substrate can also reduce crosstalk and/or other signal interference which could degrade MEM device operation. Solder bumps and/or other mounting techniques may be used to mount the MEM device substrates onto the base substrate.

### CROSS-REFERENCE TO RELATED APPLICATION

This application claims the benefit of provisional application Serial No. 60/268,784, filed Feb. 14, 2001, entitled Tiled Microelectromechanical Mirror Arrays and Fabrication Methods, the disclosure of which is hereby incorporated herein by reference in its entirety as if set forth fully herein.

### FIELD OF THE INVENTION

This invention relates to microelectronic devices and fabrication methods, and more particularly to microelectromechanical devices and fabrication methods.

### BACKGROUND OF THE INVENTION

Microelectromechanical (MEM) devices recently have been developed as alternatives for conventional electromechanical devices, such as relays, actuators, valves and sensors. MEM devices are potentially low-cost devices, due to the use of simplified microelectronic fabrication techniques. New functionality also may be provided because MEM devices can be much smaller than conventional electromechanical devices.

Arrays of MEM devices are widely used for switching, sensing and/or other applications. For example, arrays of microrelays, microsensors, microactuators and/or micromirrors may be used for many applications. More specifically, MEM mirror arrays are widely used, for example, in optical cross-connect (OXC) switches. In a MEM mirror array, an array of moveable mirrors is fabricated in a microelectronic substrate. The mirrors may be moved individually to perform optical switching.

Unfortunately, it may be difficult to fabricate large arrays of MEM devices with acceptable manufacturing yields. For example, in a 16×16 optical cross-connect switch, an array of 256 movable mirrors may be needed. It may be difficult to manufacture such an array with acceptable manufacturing yields.

### SUMMARY OF THE INVENTION

Embodiments of the invention can tile multiple MEM device substrates, such as MEM mirror substrates, on a base substrate. Each MEM device substrate can include one or more MEM devices such as mirrors. By including one or a relatively small number of devices on a MEM device substrate, the MEM device substrate can be manufactured with relatively high yield and can be tested prior to tiling onto the base substrate. The separate MEM device substrates and base substrate can also reduce crosstalk and/or other signal interference which could degrade MEM device operation. Solder bumps and/or other mounting techniques may be used to mount the MEM device substrates onto the base substrate.

### BRIEF DESCRIPTION OF THE DRAWINGS

FIG. 1 is a cross-sectional view of MEM modules according to some embodiments of the present invention.

FIGS. 2A-2D are cross-sectional views of MEM modules according to some embodiments of the present invention during intermediate fabrication steps for forming a deep oxide pad according to some embodiments of the present invention.

FIGS. 3A-3D are cross-sectional views of MEM modules according to other embodiments of the present invention during intermediate steps of fabricating a mirror according to other embodiments of the present invention.

FIGS. 4A-4I are cross-sectional views of MEM modules according to yet other embodiments of the invention during intermediate fabrication steps according to yet other embodiments of the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

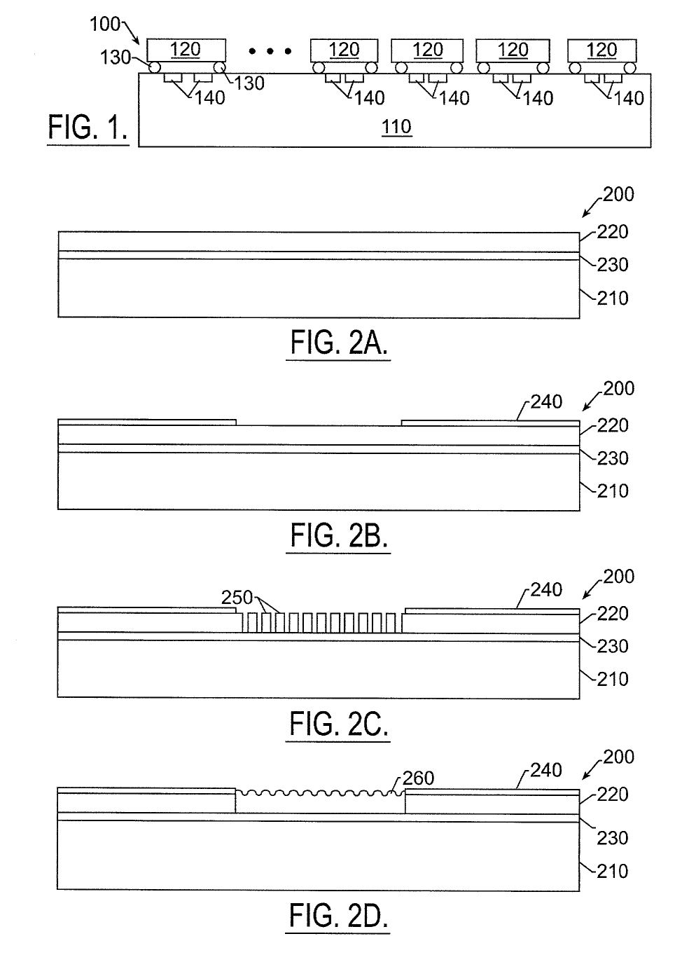

Referring to FIG. 1, a plurality of MEM device substrates, such as MEM mirror substrates 120, are mounted on a base substrate 110, to form a tiled MEM device module, such as a tiled MEM mirror module 100. The MEM mirror substrates 120 may be mounted on the base substrate 110 using solder bumps 130 and/or other mounting structures. Each MEM mirror substrate 120 can include one or more MEM mirrors, and may be fabricated as will be described below. The base substrate 110 may include mirror electrodes 140 that can be used to control movement of the mirrors in the MEM mirror substrates 120 and can also include driver electronics and/or other microelectronic devices that can be used, for example, in an optical cross-connect switch.

In some embodiments, each MEM mirror substrate 120 can include an array of four mirrors, in two rows and two columns. A 4×4 array of MEM mirror substrates 120 may be mounted on a base substrate 110 in four rows and four columns, to provide an array of 256 mirrors for a 16×16 optical cross-connect switch. This arrangement can allow higher manufacturing yields than may be obtained with a single array of 256 mirrors in a single MEM mirror substrate. It also will be understood that other numbers of mirrors and MEM mirror substrates may be used. Moreover, a single MEM mirror substrate 120 containing one or more mirrors also may be mounted on a base substrate 110.

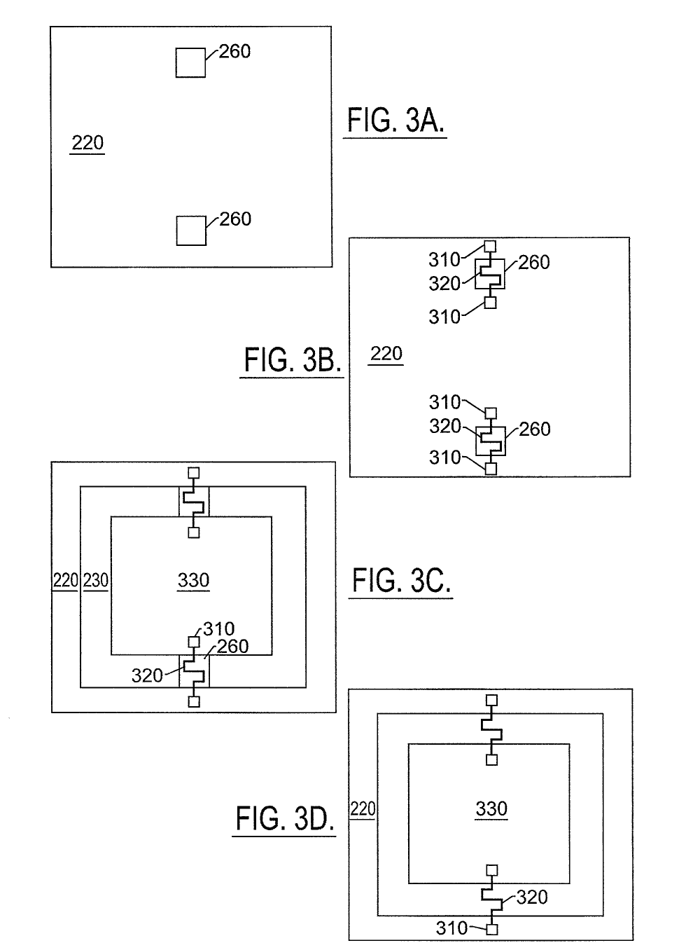

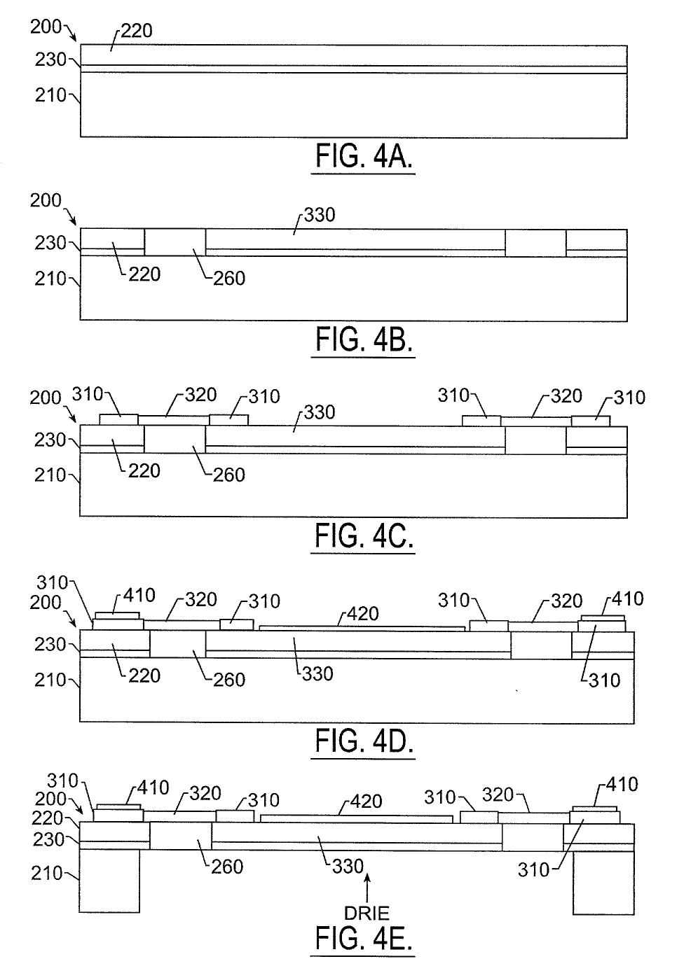

Methods of fabricating tiled MEM mirror modules 100 according to some embodiments of the invention now will be described. In fabricating MEM mirror substrates 120, a deep oxide pad process may be used. A deep oxide pad process first will be described in connection with FIGS. 2A-2D. Then, fabrication of a MEM mirror substrate 120 and mounting on a base substrate 110 will be described in connection with FIGS. 3A-3D and 4A-41.

Referring now to FIG. 2A, a Semiconductor-On-Insulator (SOI) substrate or wafer 200 is provided, that includes a bulk semiconductor region 210, a thin semiconductor-on-insulator layer 220 and a buried insulator layer 230 therebetween. Region 210 and layer 220 may comprise monocrystalline silicon, and layer 230 may comprise a buried silicon oxide layer. The design and fabrication of SOI wafers are well known to those having skill in the art and need not be described further herein.

As shown in FIG. 2B, a layer of silicon nitride 240 or other masking layer is formed and patterned. As shown in FIG. 2C, a Deep Reactive Ion Etch (DRIE) is performed through the exposed SOI layer 220 down to the buried insulator layer 230, to form an array or grating of silicon fingers 250. The array or grating of silicon fingers 250 may be formed, so as to allow thermal oxidation thereof, to form a solid silicon dioxide pad having a relatively large area and a relatively large depth. It will be understood that if silicon fingers 250 are not used, it may be difficult to fully oxidize the large area to the depth of the SOI layer 220, for example to a depth of 20 μm. It also may be difficult to form a deep, thick silicon dioxide layer using conventional chemical vapor deposition. In sharp contrast, as shown in FIG. 2C, if the silicon fingers 250 are sufficiently narrow, for example 1.81 μm wide, and have a sufficiently close pitch, such as a pitch of 3.4 μm, the silicon fingers 250 may be fully oxidized and coalesce to form an unbroken outer surface that is coplanar with SOI layer 220.

Referring now to FIG. 2D, thermal oxidation is performed to consume the silicon fingers 250 and to produce a pad oxide 260 that can fill the gaps between the fingers 250 due to the increase in volume of silicon dioxide compared to silicon, and that may be planarized to about 2000 Å. Stated differently, the dimensions of the silicon fingers 250 of FIG. 2C may be selected so as to provide a pad 260 that is fully oxidized and that is of approximately the same thickness (20 μm) as the SOI layer 220. It also will be understood that the silicon fingers 250 need not be fully consumed, as long as the pad 260 is sufficiently oxidized to planarize layer 220 and to be released during later processing steps, as will be described below. Finally, a slight rippling of the surface of the oxide pad 260 may be present, as shown in FIG. 2D, due to the oxidation of the tips of the fingers 250. This rippling can be reduced, if desired, using conventional planarization techniques.

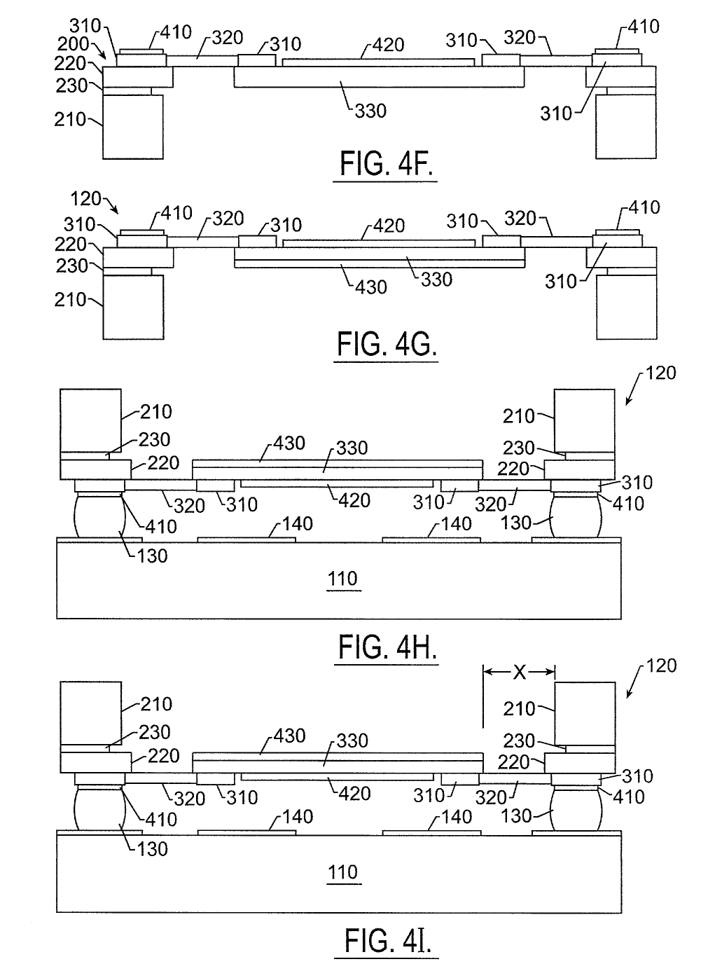

A deep oxide pad process of FIGS. 2A-2D may be used to form a MEM mirror substrate 120 using processes illustrated in FIGS. 3A-3D and 4A-4I. It will be understood that the mirrors that are fabricated in FIGS. 3A-3D have one degree of freedom (i.e., can be rotated about one axis). However, mirrors with two degrees of freedom also may be fabricated using conventional gimbal structures and used in embodiments of the invention. The mirror surface may have a thickness of between about 5 μm and about 25 μm of single crystal silicon, and may be formed in the SOI layer 220, as will be described below. A mirror hinge may be formed of 1.5 μm thick polysilicon, which can be deposited to a total thickness variation of 0.05 μm as will be described below.

Referring now to FIG. 3A, a top view of the SOI layer 220 is shown, in which the nitride mask 240 has been removed, and a pair of deep oxide pads 260 have been fabricated, for example using the fabrication process of FIGS. 2A-2D. As shown in FIG. 3B, anchors 310 and hinges 320 may be formed, for example by depositing, patterning and etching a polysilicon layer. As also shown in FIG. 3B, the hinges 320 are formed at least partially on the deep oxide pad 260, so that the deep oxide pad can become the sacrificial release layer for the hinges 320.

Then, as shown in FIG. 3C, a silicon trench or moat is etched to define the mirror 330 and a surrounding frame in the SOI layer 220. For example, deep reactive ion etching can be performed that can stop at the buried insulator layer 230, as shown in FIG. 3C. Then, as shown in FIG. 3D, the buried oxide layer 230 and the oxide pads 260 are etched, to thereby free the hinges 320 and the mirror 330. As will be shown below, the buried oxide layer 230 and deep oxide pads 260 may be etched using a backside etch and/or a frontside etch. Accordingly, a hinged mirror is formed. The thickness of the deep oxide pads 260,which are removed, can allow sufficient space for movement of the hinges 320 during actuation of the mirror 330. For example, a trench of about 20 μm in depth may be formed, which may be on the order of ten times thicker than the buried oxide layer 230.

FIGS. 4A-4I describe additional steps for fabricating MEM mirror substrates 120, and for mounting the MEM mirror substrates 120 on a base substrate 110 to form tiled MEM mirror arrays 100 such as those illustrated in FIG. 1. As with FIGS. 3A-3D, a one degree of freedom mirror is shown, but a two degree of freedom mirror can be formed using gimbal structures. Additionally, different thicknesses may be provided for the mirror and the hinge.

More particularly, as shown in FIG. 4A, an SOI wafer 200 may be provided as was described in connection with FIG. 2A. The SOI layer 220 may be between about 5 μm and about 25 μm thick in some embodiments of the invention. Then, as shown in FIG. 4B, the deep oxide pads 260 are formed, for example using a process shown in FIGS. 2A-2D. Then, in FIG. 4C, the polysilicon hinges 320 and anchors 310 may be defined as was described in FIG. 3B. The polysilicon hinges 320 and anchors 310 may be of the same thickness or different thicknesses. In some embodiments, a thickness of about 1.5 μm may be used.

Then, as shown in FIG. 4D, a layer is formed and patterned that can provide an underbump metallurgy (UBM) 410 and a mirror metal 420. As is well known, a UBM may be used as a plating base for plating solder bumps. The mirror metal 420 may provide a reflective surface and/or a stress-relieving surface opposite a second mirror surface (described below). The UBM 410 and mirror metal 420 may be patterned from a single layer, for example comprising gold.

Then, referring to FIG. 4E, the bulk semiconductor region 210 of the SOI substrate 200 may be etched, for example using deep reactive ion etching (DRIE), to expose the buried oxide layer 230. As shown in FIG. 4F, a wet etch and/or other conventional etch may be performed to remove the buried oxide layer 230 and the oxide pads 260. A single etch step also may be used. A second layer of mirror metal 430, such as gold, then may be formed on the backside of the mirror 330, as shown in FIG. 4G. It will be understood that dual mirror metal layers 420 and 430 may be used to maintain planarization of the mirror by equalizing stress, and/or to provide reflective surfaces on both faces of the mirror. The structure of FIG. 4G therefore can provide a complete MEM mirror substrate 120. It will be understood that, as was described above, multiple mirrors may be formed on the MEM mirror substrate 120.

Referring now to FIG. 4H, the MEM mirror substrate 120 is mounted onto a base substrate 110, also referred to as an IC/electrode die, for example using solder bumps 130 and/or other conventional techniques. It will be understood that solder bumps may be used, because they can provide a controlled separation between the MEM mirror substrate 120 and the base substrate 110, and also can provide lateral alignment of the MEM mirror substrates 120 relative to the base substrate 110. Electrostatic actuator electrodes 140 and/or other microelectronic devices also may be formed in the base substrate 110. As shown in FIG. 41, adequate space x, such as a 35 μm space, may be maintained between the edge of the mirror 430 and the bulk silicon region 210 that remains, so as to prevent the bulk silicon region 210 from shadowing optical reflection from the mirror 330, for a mirror tilt of up to four degrees. For larger tilts, larger gaps may need to be present and/or the bulk silicon layer 210 may be fully or partially removed.

It also will be understood that, although FIGS. 4H and 4I show only a single MEM mirror substrate 120 flip-chip mounted on a base substrate 110, multiple MEM mirror substrates 120 may be flip-chip mounted on the base substrate 110, as was described in FIG. 1. Accordingly, MEM mirror substrates may be fabricated with improved yield and then may be packaged to form a larger MEM mirror array that may be used, for example, for optical cross-connect switching.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A microelectromechanical (MEM) module comprising:
a plurality of MEM device substrates, each of which includes at least one MEM device thereon;
a base substrate including a face; and
a mounting structure that is configured to mount the plurality of MEM device substrates on the face.

2. A MEM module according to claim 1 wherein each of the MEM device substrates includes an array of M rows and N columns of MEM devices thereon and wherein the mounting structure is configured to mount the plurality of MEM device substrates in an array of R rows and S columns on the face to thereby provide a tiled array of M×R rows and N×S columns of the MEM devices in the MEM module.

3. A MEM module according to claim 2 wherein the MEM devices comprise movable MEM mirrors.

4. A MEM module according to claim 2 wherein the mounting structure comprises a plurality of solder bumps that are configured to mount the plurality of MEM device substrates on the face.

5. A MEM module according to claim 4 wherein the MEM device substrate includes first and second opposing faces, wherein the at least one MEM device is adjacent the first face and remote from the second face and wherein the first faces of the MEM device substrates are adjacent the face of the base substrate.

6. A microelectromechanical (MEM) mirror module comprising:
a plurality of MEM mirror substrates, each of which includes a mirror comprising monocrystalline silicon, a frame comprising monocrystalline silicon that is spaced apart from and at least partially surrounds the mirror and at least two hinges between the mirror and the frame;
a base substrate including a face; and
a mounting structure that is configured to mount the frames of the plurality of MEM device substrates on the face.

7. A MEM mirror module according to claim 6 wherein the frame is a first frame, each of the MEM mirror substrates also comprising an insulator layer on the first frame, opposite the mounting structure, and a second frame that is thicker than the first frame, on the insulator layer opposite the first frame.

8. A MEM mirror module according to claim 6 wherein the mirror includes a pair of opposing faces and wherein each of the MEM mirror substrates further comprises a metal layer on each of the opposing faces of the mirrors.

9. A MEM mirror module according to claim 8 wherein the mounting structure comprises a plurality of solder bumps that are configured to mount the plurality of MEM device substrates on the face.

10. A MEM mirror module according to claim 9 wherein each of the MEM mirror substrates further comprises an underbump metallurgy between the frame and the solder bumps and wherein the underbump metallurgy and the metal layer on the MEM mirror substrate that is adjacent the base substrate both comprise a same metal.

11. A MEM mirror module according to claim 6 wherein each of the MEM mirror substrates includes an array of M rows and N columns of MEM mirrors thereon and wherein the mounting structure is configured to mount the plurality of MEM mirror substrates in an array of R rows and S columns on the face to thereby provide a tiled array of M×R rows and N×S columns of the MEM mirrors in the MEM mirror module.

12. A method of fabricating a microelectromechanical (MEM) mirror module comprising:
providing a silicon-on-insulator substrate that includes a monocrystalline silicon layer on a bulk silicon substrate, with an insulator layer therebetween;
fabricating at least two spaced apart pads in the monocrystalline silicon layer that extend through the monocrystalline silicon layer to the insulator layer;
fabricating at least one hinge on each of the at least two spaced apart pads;
defining a mirror and a frame that at least partially surrounds the mirror, in the monocrystalline silicon layer, such that the hinges bridge the mirror and the frame; and
forming a metal layer on at least a portion of the mirror and at least a portion of the frame, opposite the insulator layer.

13. A method according to claim 12 further comprising:
etching the bulk silicon substrate to expose the insulator layer adjacent the mirror and adjacent the pads; and
etching the insulator layer adjacent the mirror and the pads to release the mirror and the hinges.

14. A method according to claim 13 wherein the metal layer is a first metal layer, the method further comprising:
forming a second metal layer on the mirror opposite the first metal layer.

15. A method according to claim 14 further comprising:
mounting the silicon-on-insulator substrate on a base substrate, with the hinges and the first metal layer adjacent the base substrate and the second metal layer remote from the base substrate.

16. A method according to claim 15 wherein the mounting comprises:
flip-chip mounting the silicon-on-insulator substrate on the base substrate using a plurality of solder bumps.

17. A method of fabricating a movable microeoectromechanical (MEM) structure comprising:
etching an array of features in a silicon substrate;
at least partially thermally oxidizing the array of features to form a pad comprising silicon dioxide in the silicon substrate;
forming a movable MEM structure on the pad; and
removing the pad to release the movable MEM structure.

18. A method according to claim 17 wherein the etching comprises etching an array of features in a silicon layer on an insulator layer on a substrate.

19. A method according to claim 17 wherein the features are between about 5 μm and about 25 μm thick.

20. A method according to claim 18 wherein the removing comprises:
etching the substrate adjacent the pad;
etching the insulating layer adjacent the pad; and
etching the pad, from the insulating layer that was removed to the movable MEM structure.
